(19) United States
(12) Patent Application Publication
(10) Pub. No.: US 2015/0276686 A1
(43) Pub. Date: Oct. 1, 2015

(54) SYSTEMS AND METHODS FOR ADDRESSING ONE OR MORE SENSORS ALONG A CABLE

(71) Applicant: General Electric Company, Schenectady, NY (US)

(72) Inventors: William Albert Challener, Niskayuna, NY (US); Sachin Narahari Dekate, Niskayuna, NY (US); Sabarni Palit, Guilderland, NY (US); Ansas Matthias Kasten, Niskayuna, NY (US); Reza Ghandi, Niskayuna, NY (US)

(73) Assignee: General Electric Company, Schenectady, NY (US)

(21) Appl. No.: 14/225,768

(22) Filed: Mar. 26, 2014

(51) Int. Cl. G01N 29/42; G01N 29/24; E21B 47/06; B81B 7/02

(52) U.S. Cl. CPC G01N 29/42; B81B 7/02; G01N 29/2418; E21B 47/06; G01N 2291/014; G01N 2291/02881; G01N 2291/02872

(57) ABSTRACT

A sensor interrogation unit in one embodiment includes a control module, a reading module, and a determination module. The control module is configured to control one or more lasers to provide a pulsed signal to at least one sensor. Each period of the pulsed signal has a first component having a first intensity and a second component having a second intensity that is lower than the first intensity. The reading module is configured to receive at least one return signal comprising reflections of the pulsed signal from the at least one sensor, to read one of the first component or the second component, and to provide frequency information based on the read reflections. The determination module is configured to determine at least one resonant frequency of the at least one sensor based on the frequency information.

### STATEMENT REGARDING FEDERALLY SPONSORED RESEARCH AND DEVELOPMENT

This invention was made with government support under U.S. Government Contract Number DE-EE0002787 awarded by the Department of Energy, and under Government Contract Number DE-FE0010116. The U.S. Government may have certain rights in this invention.

### BACKGROUND

Various devices have been developed for measuring environmental conditions of a given location, such as temperature or pressure. However, numerous locations present challenges to many of these devices. For example, many devices may not be appropriate for use in higher temperature environments, such as geothermal wells, oil wells, or the like.

Certain sensors may be appropriate for use in such challenging environments. Micro-electromechanical system (MEMS) sensors have been utilized, for example, to measure pressure in challenging environments such as geothermal wells. A relationship between a resonant frequency of a MEMS sensor and the pressure may be utilized to measure pressure, for example. Such sensors may be conventionally interrogated using a first laser modulated at the resonant frequency of the sensor, and using a second laser to provide a generally constant light level at a different wavelength for measuring the vibration amplitude of the sensor. However, in order to continuously modulate the sensor at the resonant frequency, a readout signal is incorporated into a relatively complex feedback loop to vary the modulation frequency in order to track the resonant frequency of the sensor (e.g., to determine a local pressure).

Such conventional approaches may suffer from one or more drawbacks. For example, the feedback mechanism for modulating the laser at the resonant frequency of the sensor may be quite complex, expensive, and/or inconvenient to use. As another example, conventional approaches may not lend themselves to use with multiple sensors disposed in a remote location, such as a well. For example, conventional approaches require the use of two lasers per sensor, which may result in considerable expense to provide and maintain a system using multiple sensors.

### BRIEF DESCRIPTION

In one embodiment, a sensor interrogation unit is provided that includes a control module, a reading module, and a determination module. The control module is configured to control one or more lasers to provide a pulsed signal to at least one sensor. Each period of the pulsed signal has a first component having a first intensity and a second component having a second intensity that is lower than the first intensity. The reading module is configured to receive at least one return signal comprising reflections of the pulsed signal from the at least one sensor, to read one of the first component or the second component, and to provide resonant frequency information based on the read reflections. The determination module is configured to determine at least one resonant frequency of the at least one sensor based on the resonant frequency information.

In another embodiment, a method (e.g., a method for interrogating at least one sensor) is provided includes providing a pulsed laser signal to at least one sensor. Each period of the pulsed laser signal has a first component having a first intensity and a second component having a second intensity that is lower than the first intensity. The method also includes obtaining at least one return signal comprising reflections of the pulsed signal from the at least one sensor. Further, the method includes reading, with at least one processing unit, reflections of at least one of the first component or the second component. Also, the method includes determining, with the at least one processing unit, resonant frequency information of the return signal based on the at least one of the first component or the second component that is read. The method further includes determining, with the at least one processing unit, at least one resonant frequency of the at least one sensor based on the resonant frequency information.

In another embodiment, a tangible and non-transitory computer readable medium is provided (e.g., for interrogating at least one sensor). The tangible and non-transitory computer readable medium includes one or more computer software modules configured to direct one or more processors to provide a pulsed laser signal to at least one sensor. Each period of the pulsed laser signal has a first component having a first intensity and a second component having a second intensity that is lower than the first intensity. The computer readable medium is also configured to direct the one or more processors to obtain at least one return signal comprising reflections of the pulsed signal from the at least one sensor. The computer readable medium is further configured to direct the one or more processors to read reflections of at least one of the first component or the second component. Also, the computer readable medium is configured to direct the one or more processors to determine resonant frequency information of the return signal based on the at least one of the first component or the second component that is read. Further, the computer readable medium is also configured to direct the one or more processors to determine at least one resonant frequency of the at least one sensor based on the resonant frequency information.

### BRIEF DESCRIPTION OF THE DRAWINGS

FIG. 1 is a schematic block diagram of a measurement system in accordance with various embodiments.

FIG. 2 depicts an example pulsed signal in accordance with various embodiments.

FIG. 3 depicts an example reflected signal responsive to the pulsed signal of FIG. 2 in accordance with various embodiments.

FIG. 4 depicts another example pulsed signal in accordance with various embodiments.

FIG. 5 an example of a raw reflective signal of reflections of the second portion of a pulsed signal in accordance with various embodiments.

FIG. 6 depicts a spectral resonance of the reflective signal of FIG. 5 in accordance with various embodiments.

FIG. 7 is a schematic block diagram of a measurement system in accordance with various embodiments.

FIG. 8 is a schematic block diagram of a measurement system in accordance with various embodiments.

FIG. 9 is a flowchart of a method in accordance with various embodiments.

### DETAILED DESCRIPTION

Various embodiments will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors, controllers or memories) may be implemented in a single piece of hardware (e.g., a general purpose signal processor or random access memory, hard disk, or the like) or multiple pieces of hardware. Similarly, any programs may be stand-alone programs, may be incorporated as subroutines in an operating system, may be functions in an installed software package, and the like. It should be understood that the various embodiments are not limited to the arrangements and instrumentality shown in the drawings.

As used herein, the terms “system,” “unit,” or “module” may include a hardware and/or software system that operates to perform one or more functions. For example, a module, unit, or system may include a computer processor, controller, or other logic-based device that performs operations based on instructions stored on a tangible and non-transitory computer readable storage medium, such as a computer memory. Alternatively, a module, unit, or system may include a hard-wired device that performs operations based on hard-wired logic of the device. The modules or units shown in the attached figures may represent the hardware that operates based on software or hardwired instructions, the software that directs hardware to perform the operations, or a combination thereof. The hardware may include electronic circuits that include and/or are connected to one or more logic-based devices, such as microprocessors, processors, controllers, or the like. These devices may be off-the-shelf devices that are appropriately programmed or instructed to perform operations described herein from the instructions described above. Additionally or alternatively, one or more of these devices may be hard-wired with logic circuits to perform these operations.

As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Generally, various embodiments provide devices, systems, and/or methods for interrogating sensors such as micro-electromechanical system (MEMS) sensors. Various embodiments may be utilized in conjunction with interrogating one or more MEMS sensors remotely positioned in a well, for example a geothermal well, a well used in conjunction with oil or gas exploration or extraction, or a well used in conjunction with hydraulic fracturing, as examples. For additional details regarding MEMS sensors and the use of MEMS sensors, for example, to detect one or more measurands such as temperature or pressure, see U.S. patent application Ser. No. 13/954,296 (referred to herein as “the 296 application), entitled, “Systems and Methods for Pressure and Temperature Measurement,” filed Jul. 30, 2013, the entire subject matter of which is hereby incorporated in its entirety. In some embodiments, plural sensors (e.g., MEMS sensors) may be coupled to a single shared cable using, for example, one or more wavelength division multiplexers (WDMs). A separate laser wavelength may be used for each sensor, with laser energy for each wavelength inserted or provided into the shared cable, with individual wavelengths split off at or near each sensor for use with the particular sensor. As used herein, a “laser wavelength” may be understood as including a relatively narrow bandwidth centered about a nominal value. For example, a laser wavelength of about 1310 nanometers may be understood as a wavelength channel including laser energy within a relatively narrow range (e.g., plus or minus about 2 or 3 nanometers). In some embodiments, laser energy (e.g., a read signal) may be distributed among sensors via a power splitting arrangement.

In contrast to conventional schemes that require two lasers per sensor, in various embodiments a single laser wavelength may be utilized per sensor for both drive (or excitation) of one or more sensors and readback of information from one or more sensors. This may be accomplished in some embodiments via the use of a pulsed laser signal including a periodic high power laser pulse to excite or drive the MEMS sensor (e.g., a resonator or similar structure(s) of the sensor) followed by a low power laser level to read the reflected ring down signal as the sensor responds to the excitation pulse and settles after initially being subjected to the pulse. For example, for sensors with a Q (or quality factor) of about 20,000, a sensor will exhibit ring down (or time to settle from an initial pulse to vibrations at or near zero amplitude) on the order of about 1 second.

In some embodiments, the ring down signal, or reflected signal read using the low level laser portion of the pulsed signal, may be Fourier transformed to determine one or more peak (e.g., maximum or relative maxima) ring down frequencies. Peak frequencies may be identified as resonant frequencies and used to determine at least one of temperature or pressure based on a relationship between resonant frequency of the MEMS sensor and at least one of temperature or pressure. In some embodiments, one or more MEMS sensors may be excited and read to determine resonant frequency(ies) without requiring a complex feedback circuit and instead utilizing a relatively simple analog-to-digital converter operating at a relatively low frequency.

Various embodiments reduce the number of lasers or other devices required to drive and read one or more sensors. For example, for a single sensor, in some embodiments the number of lasers used to drive and read the sensor may be reduced from two to one. Various embodiments enable the use of wavelength division multiplexing allowing multiple sensors to be operably coupled to a single shared fiber optic. Additionally or alternatively, various embodiments provide simultaneous measurement of multiple resonant frequencies of a sensor die, permitting simultaneous determination of both pressure and temperature, as further discussed in the 296 application. Various embodiments eliminate the need to unlock a feedback loop, scan to a new resonant frequency, and then relock the loop before measuring the second resonant frequency as may be performed with conventional interrogation techniques.

It may be noted that, while the laser pulse power for the periodic high energy laser pulse in various embodiments may be relatively high, the amount of energy delivered to the sensor may be quite low due to a relatively short duration of the periodic high energy laser pulse and relatively slow repetition rate. By way of example, in some embodiments, a laser peak power of about 750 milliWatts may be provided during the periodic high energy laser pulse. However, the high energy pulse may occur for only about ten microseconds and repeat about every second, such that the average power delivered to the sensor for driving or exciting the sensor may be about 8 microWatts (an additional amount of energy may be delivered to the sensor at a relatively low energy level to read the sensor). By way of comparison, conventional interrogation techniques may deliver an average power of about 1 milliWatt or more. Thus, using certain conventional techniques, the drive laser may result in heating of the sensor, which may affect temperature readings determined using the sensor. By delivering less energy to the sensor, various embodiments eliminate or reduce heating of the sensor and resulting drawbacks.

It may be noted that the delivery of light may be understood in terms of energy/pulse. For example, in embodiments utilizing a pulse picker to select pulses for delivery to one or more sensors, a pulsed laser may emit on average about 250 milliWatts, but a relatively large proportion of that power may be diverted from the sensor(s) by the pulse picker. For example, an energy per pulse may be about 25 milliJoules. If each pulse is about 10 microseconds long, and if one pulse per second is delivered to a sensor, the average power may be about 0.25 microWatts. Further, a relatively large amount of light may be lost via the pulse picker and fiber optics before the light reaches the sensor, so the amount of power from the pulsed laser that reaches the sensor may be about 50 nanoWatts or less. The required pulse length may be determined based on the vibrational frequencies of the MEMS device being interrogated. The required pulse length may be selected to be relatively short compared to the period of the highest vibrational frequency. In some embodiments, the pulse length may be about 1/10 or less than the period of the highest resonant frequency or highest frequency desired to be measured. For example, for a MEMS device having vibrational frequencies up to about 100 kiloHertz, the length of the pulse may correspond to about 1/100 kiloHertz or about 10 microseconds or less. As another example, for MEMS devices that vibrate at frequencies of about 1 MegaHertz, the length of the pulse may be about 1 microsecond or less, for example about 0.1 microsecond or less. The vibrational frequencies, and the desired length of pulse, may vary with the particular design of MEMS sensor.

At least one technical effect of various embodiments is reducing equipment (e.g., number of lasers and related equipment). At least one technical effect of various embodiments is reduced energy delivered to drive sensor and improved accuracy (e.g., by reducing or eliminating heating of the sensor). At least one technical effect of various embodiments is providing for use of a single cable with multiple sensors. At least one technical effect of various embodiments is removing the need for a feedback loop to drive and read one or more MEMS sensors. At least one technical effect of various embodiments is improved reliability and/or reduced cost of measuring parameters (e.g., temperature and pressure in challenging remote environments.

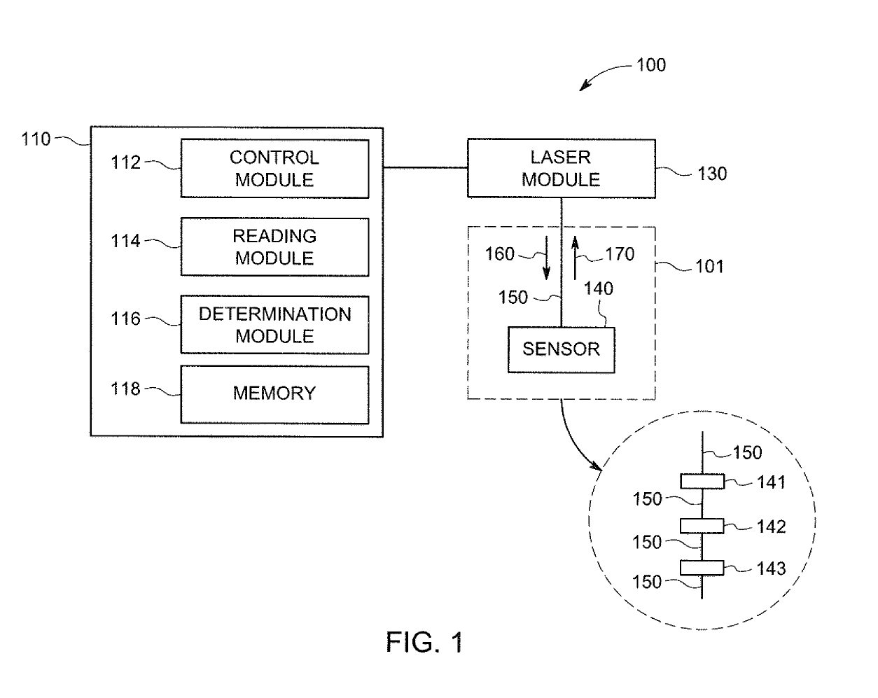

FIG. 1 is a schematic view of a measurement system 100 formed in accordance with various embodiments. The measurement system 100 may be used to measure environmental conditions (e.g., one or more of temperature or pressure) at one or more locations disposed within a remote environment 101. The remote environment 101 may, for example, be a well used in oil or natural gas applications. The measurement system 100 includes an interrogation unit 110, a laser module 130, a sensor 140, and a cable 150. In the illustrated embodiment, the sensor 140 and at least a portion of the cable 150 are disposed within the remote environment 101, with the sensor 140 used to determine one or more environmental conditions or states (e.g., pressure, temperature) of the remote environment 101, while the interrogation unit 110 and the laser module 130 are disposed outside of the remote environment 101, thus preventing the interrogation unit 110 and the laser module 130 from harsh conditions of the remote environment 101. The interrogation unit 110 and the laser module 130 thus may be understood as being located remotely from the sensor 140 (and vice versa). It may be noted that one or more aspects of the interrogation unit 110 and laser module 130 may be shared as part of a common unit or device.

Generally, for the illustrated embodiment, the interrogation unit 110 is configured to control the laser module 130 to provide a pulsed signal 160 to the sensor 140. One portion or component of the pulsed signal 160 (e.g., a relatively high energy pulse) may be delivered to drive or excite the sensor 140 to resonate, while another portion or component of the pulsed signal 160 is at a lower energy (in some embodiments a relatively low energy for reading, in some other embodiments at or near zero amplitude) to allow the sensor to settle or ring down. The interrogation unit 110 also receives reflections 170 of the pulsed signal from the sensor 140, either directly or indirectly (e.g., via the laser module 130 as shown in FIG. 1). The interrogation unit 110 reads the reflections 170 (reading a signal as used herein may be understood as including collecting or obtaining information during one or more sampling periods for later use or analysis) to derive, determine, or otherwise provide frequency information (e.g., resonant frequency information or information from which resonant frequency may be determined or derived). In some embodiments, the reflections that are read may be the reflections of all or a portion of a low energy portion of the pulsed signal 160, while in other embodiments, the reflections that are read may be the reflections of all or a portion of a high energy portion of the pulsed signal 160. The depicted interrogation unit 110 is further configured to determine at least one resonant frequency of the sensor 140 based on the frequency information provided from the reflections 170. The determined resonant frequency(ies) may be used to determine one or more of pressure or temperature proximate the sensor 140 in the remote environment 101.

The depicted interrogation unit 110 includes a control module 112, a reading module 114, a determination module 116, and a memory 118. The interrogation unit 110 may be understood as an example of a processing unit. Software or other instructions may be stored in the memory 110 and used to instruct one or more processing circuits to perform operations discussed herein.

The control module 112 is configured to control one or more lasers (e.g., the laser module 130) to provide a pulsed signal (e.g., the pulsed signal 160) to at least one sensor (e.g., the sensor 140). The control module 112, for example, may generate and/or transmit control signals to one or more lasers and/or related equipment or components to produce a desired pulsed signal. For example, the control module 112 may include processing circuitry configured to generate the control signals as well as a port (or have access to a port) configured to communicably couple the control module 112 with the laser module 130. Each period of the pulsed signal includes a first component having a first intensity and a second component having a second intensity that is lower than the first intensity. In some embodiments, the first component may occupy a relatively small proportion of the total time of the period and the second component may occupy a relatively large proportion of the total time. Generally, the first component is used to excite or drive the sensor 140, causing the sensor 140 to vibrate at a relatively high amplitude. After initial exposure to the high energy pulse, the sensor 140 may begin to ring down as the amplitude of vibrations of the sensor 140 decay or reduce. Reflections off the sensor 140 during this ring down period may be read and analyzed by the interrogation unit 110 as discussed herein to determine one or more resonant frequencies of the sensor 140.

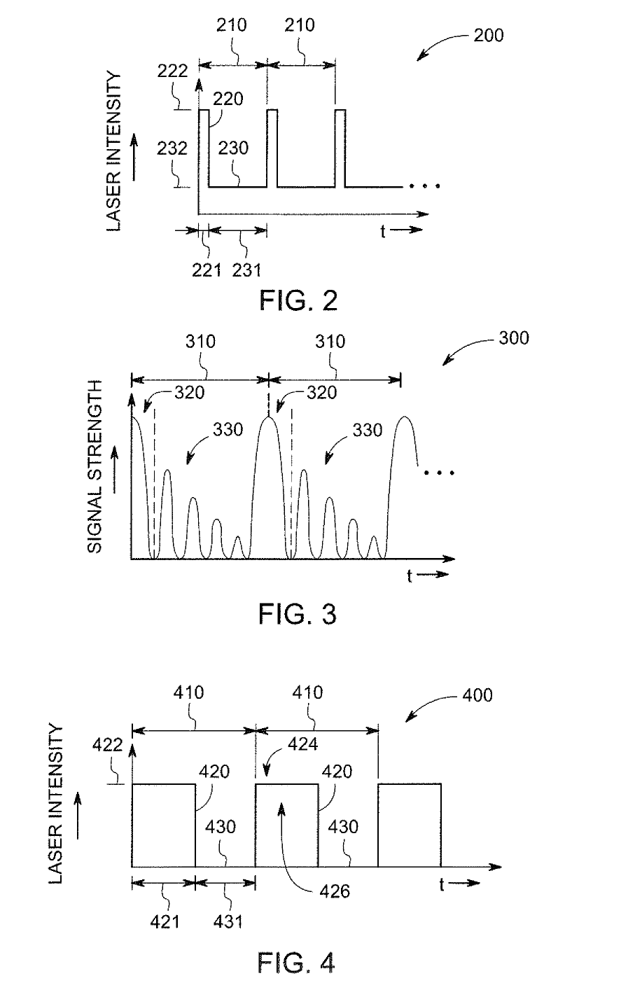

FIG. 2 depicts one example of a pulsed signal 200 plotted on a vertical axis corresponding to laser intensity and a horizontal axis corresponding to time. The pulsed signal 200, for example, may be provided by the laser module 130 under the control of the control module 112 of the interrogation unit 110. As seen in FIG. 2, the depicted pulsed signal 200 has a first component 220 and a second component 230 and repeats over a period 210. The first component 220 occupies a beginning portion of the period 210 and the second component 230 occupies an ending portion of the period 210. As used herein, a component of a signal may be understood as the portion of the signal corresponding to a specified amplitude characteristic provided by a laser or other light source. Thus, a component of a signal provided to a sensor may include a portion of the signal provided at a nominal energy level, while a component of a reflected signal may be understood as the portion of the reflection caused by a component of the signal causing the reflection.

The first component 220 has a first intensity 222 that is greater than a second intensity 232 of the second component 230. The first component 220 may be understood as a drive or excitation portion or component, and the second component 230 may be understood as a read or data collection portion or component. For the example pulsed signal 200 depicted in FIG. 2, different components of the pulsed signal are used for driving and reading the sensor. For example, the interrogation unit 110 may disregard reflections of the first component 220 and use only all or a portion of reflections of the second component 230 to provide frequency information to be used in determining one or more resonant frequencies. It may be noted that a number of periods 210 may be provided to the sensor, with the reflections from plural second components 230 averaged, for example, to reduce effects of noise. The first intensity 222 is configured to provide sufficient energy to cause the sensor to vibrate a sufficient amount of time at sufficiently high amplitudes to provide enough information to determine one or more resonant frequencies. Because the first intensity 222 is sufficient to excite or cause measurable vibration at different resonant frequencies of the sensor simultaneously, modulation of the pulsed signal requiring a feedback loop is not required. The second intensity 232 is configured to provide light energy to produce reflections from which the vibration of the sensor during the ring down period may be analyzed to determine the one or more resonant frequencies. The second intensity 232 may be maintained at a relatively low energy to eliminate or reduce excitation of the sensor by second component 230 and/or to minimize energy delivered to the sensor during a reading period (and thereby reducing total or average energy delivered to the sensor). In various embodiments, the particular intensities used and/or type of pulsed signal used may be selected, configured, or tuned based on the particular properties of the sensor(s) to be interrogated (e.g., Q value or other measure of amplitude sensitivity to changes in frequency near resonant frequencies, decay characteristics, or the like).

The first component 220 has a duration 221 and the second component 230 has a duration 231. The duration 231 of the second component 230 may be relatively long relative to the duration 221 of the first component 220. For example, the period 210 may be about one second, and the first component 220 may have a duration 221 of only about 10 microseconds per period. The relatively short duration 221 of the higher energy first component 220 may be utilized to reduce total energy delivered to the sensor per period 210, or average energy delivered to the sensor by the pulsed signal 200. The duration 221 of the first component 220 may be relatively short compared to periods of resonant modes of the sensor, allowing the sensor time to ring down between delivery of the high energy pulse or first component 220. The duration 221 of the first component 220, which is used to excite one or more sensors, may be sized based on the design of the sensor(s) to be excited and read. The duration 221 may be selected to be relatively short relative to the period(s) of the vibration of the sensor to be read. For example, the duration 221 may be about 1/10 or less than the period of the highest frequency of the sensor(s) which is desired to be measured or determined.

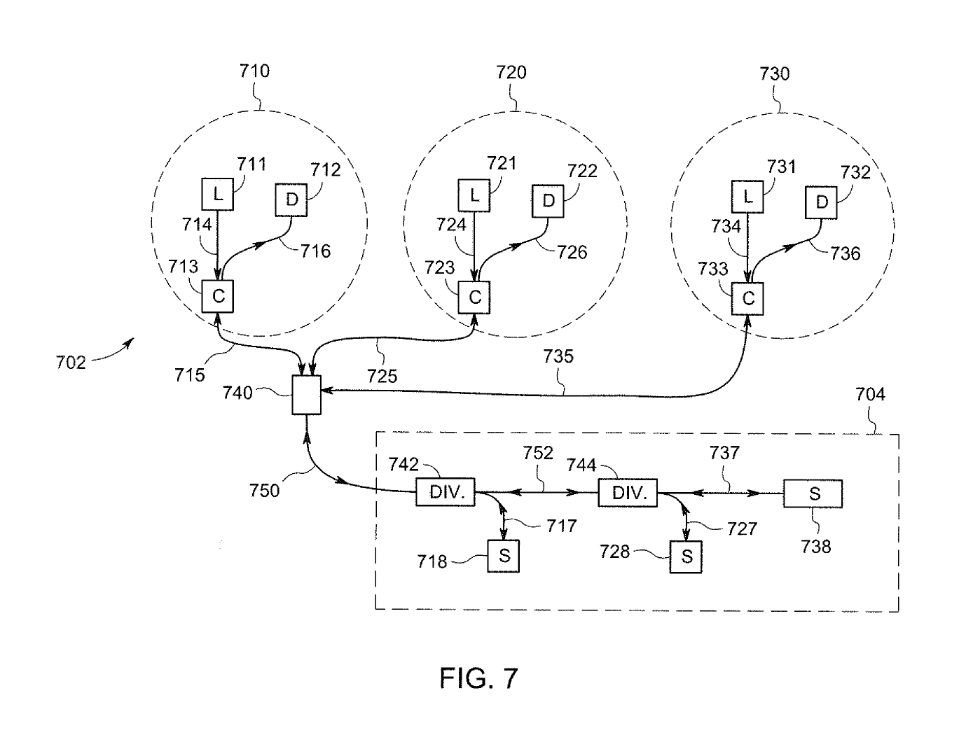

It may be noted that the pulsed signal 200 may be provided by the same laser in some embodiments or by different lasers in other embodiments. For example, in some embodiments, the amplitude of a laser having a nominal wavelength (e.g., 1310 nanometers) may be adjusted during each period 210 to provide the first component 220 and the second component 230. It may further be noted that, for use with a plurality of sensors, each sensor may have a laser dedicated thereto, with each of the lasers occupying a different wavelength or bandwidth, so that the signals from the lasers may be combined on a single cable and split off, based on wavelength, to corresponding sensors. A first laser may produce a pulsed signal at a first wavelength for driving and reading a first sensor, a second laser may produce a pulsed signal at a second wavelength for driving and reading a second sensor, and so on. Thus, for a total of n sensors, only a total of 1 cable and n lasers may be needed, in contrast to conventional techniques that may require a total of 2*n lasers and a total of n cables for a total of n sensors. An example of such an arrangement is provided in connection with FIG. 7 and the related discussion.

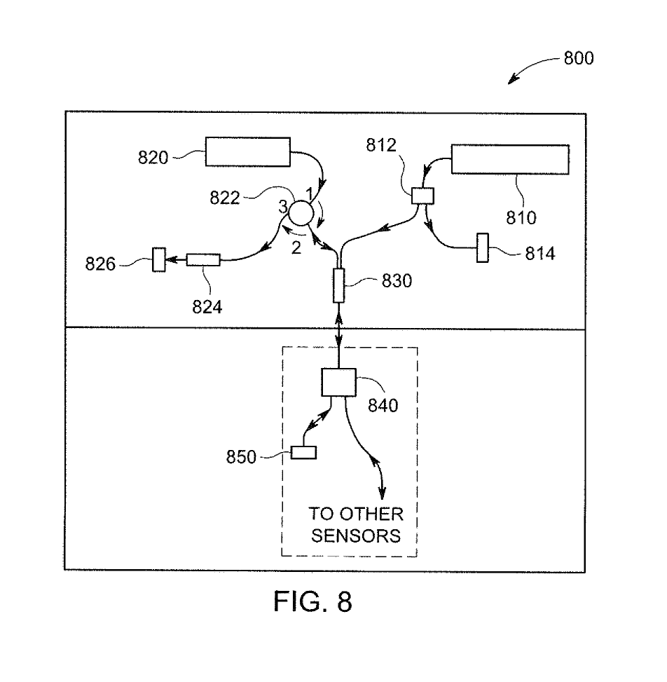

Returning to FIG. 2, it may be noted that in some embodiments, however, the first component 220 and the second component 230 of the pulsed signal 200 may be provided by different lasers. For example, a relatively high energy laser may be cycled between on and off positions to provide the first component 220 and a relatively low energy laser may be cycled between on and off position to provide the second component 230. Alternatively, the relatively low energy laser may be maintained at a constant level, and the first intensity 222 may correspond to the sum of the energies from the high and low energy lasers, while the second intensity 232 corresponds to the energy of the low energy laser only. In some embodiments, the high energy laser providing the first component 220 and the low energy laser providing the second component 230 may operate at or about the same wavelength, while in other embodiments the high and low energy lasers may operate at different wavelengths. It may be noted that, for embodiments using separate lasers for the first and second components, a single drive or excitation laser (or other source of light energy) may be used to provide the first component 220 (e.g., a drive or excitation signal, portion, or component) to the sensors, while a separate read laser may be employed for each sensor. Similar to the above discussion, each sensor may have a read laser dedicated thereto, with each of the read lasers occupying a different wavelength or bandwidth, so that the signals from the read lasers may be combined on a single cable and split off, based on wavelength, to corresponding sensors. A first read laser may produce a pulsed signal at a first wavelength for reading a first sensor, a second read laser may produce a pulsed signal at a second wavelength for reading a second sensor, and so on. Thus, for a total of n sensors, only a total of 1 cable and n+1 lasers (e.g., n read lasers and 1 drive laser) may be needed, in contrast to conventional techniques that may require a total of 2*n lasers and a total of n cables for a total of n sensors. In still other embodiments, a read laser may be shared among sensors, requiring in the use of 2 total lasers for plural sensors. An example of an embodiment utilizing different lasers for the drive and read portions of a pulsed signal is provided in connection with FIG. 8 and the related discussion.

Returning to FIG. 2, as indicated herein, the first component 220 or high energy pulse may be applied for a relatively small proportion of the period 210, allowing a sensor receiving the pulsed signal. The signal (and reflections of the signal) may be broken into separate parts for exciting a sensor and reading a sensor. FIG. 3 illustrates an example of a reflected signal 300 (e.g., a signal produced by a sensor responsive to reception of a pulsed signal such as the pulsed signal 200) plotted on a vertical axis corresponding to signal strength (e.g., strength of the reflected signal) and a horizontal axis corresponding to time. As seen in FIG. 3, the reflected signal 300 has a period 310 corresponding to the period of a received signal (e.g., period 210 of pulsed signal 200).

The reflected signal 300 includes a first component 320 and a second component 330. The first component 320 represents the reflections during a drive or excitation period (e.g., the reflections caused by the first component 220 of the pulsed signal 200), while the second component 330 represents the reflections during a read period (e.g., the reflections caused by the second component 230 of the pulsed signal 200). As seen in FIG. 3, the reflected signal 300 may be seen as a generally sinusoidal signal of decreasing amplitude throughout the period 310, with the amplitude sharply increasing at the delivery of a subsequent high energy pulse and beginning of a subsequent period 310. For the depicted reflected signal 300, the interrogation unit 110 may disregard the first component 320 of the reflected signal 300. For example, non-resonant frequencies may be initially excited at a high level during the relatively short duration of the high energy pulse of the first component 220 that may be render the identification of resonant frequencies difficult over the duration of the first component 320. Instead, the interrogation unit 110 may collect or analyze the second component 330. For example, information describing the second component 330 for a relatively large number of sampled periods 310 (e.g., 100 samples or 1000 samples, among others) may be averaged and Fourier transformed to provide frequency information from which one or more resonant frequencies may be identified.

It may be noted that the particular pulsed signal 200 and reflected signal 300 are provided by way of example for illustrative purposes, and that other signal shapes or types may be utilized in various embodiments. For example, additional or different components may be utilized in various embodiments, a pulsed signal may have one or more blank portions (or portions having an amplitude of zero or about zero), transition portions between components, other shapes and/or proportions of signals, other proportions of durations for signal components, or the like. As another example, the second component 330 of the reflected signal 300, which may be understood as corresponding to a ring down period of a sensor after the sensor has been excited, may be symmetric about a horizontal axis, or about an offset (e.g., a DC offset) from a horizontal axis.

FIG. 4 provides an example of a pulsed signal 400 that has an amplitude of about zero during a low or minimum portion of the pulsed signal 400. Because the low energy portion of the pulsed signal 400 is about zero, a corresponding reflected signal will be at or about zero. Thus, the vibration of the sensor during the low energy portion of the pulsed signal 400 may not be obtained or read by the interrogation unit 110. Therefore, in contrast to embodiments where reflections are read during a low energy portion (e.g., the second component 230 of the signal 200), for the embodiment depicted in FIG. 4 reflections must be read during the high energy portion of the signal. For example, an initial portion or leading edge of the pulsed signal 400 may result in a ringing of the sensor, and a later portion or trailing portion of the pulsed signal 400 may be read and used to determine one or more resonant frequencies. A single laser may be cycled on and off to provide the pulsed signal 400.

The pulsed signal 400 as shown in FIG. 4 is plotted on a vertical axis corresponding to laser intensity and a horizontal axis corresponding to time. The pulsed signal 400, for example, may be provided by the laser module 130 under the control of the control module 112 of the interrogation unit 110. As seen in FIG. 4, the depicted pulsed signal 400 has a first component 420 and a second component 430 and repeats over a period 410. The first component 420 occupies a beginning portion of the period 410 and the second component 430 occupies an ending portion of the period 410.

As indicated above, in some embodiments using a pulse to excite a sensor and a separate portion of a signal to read vibrations of the sensor, the length of the pulse may be relatively short relative to the vibrational frequencies of the sensor. However, for the embodiment depicted in FIG. 4, the beginning portion 410 of the signal is used both to read and excite the sensor, so that the length of the beginning portion 410 may be longer than the vibrational frequencies. The rise time of the beginning portion 410 may be selected to be relatively short relative to the vibration period(s) of a sensor to be excited and read by the signal 400. For example, for such a wave (e.g., a square wave), the rise time or turn-on time (e.g., the time for the signal to go from off to on) may be shorter than the period corresponding to the highest frequency of the sensor to be measured or determined, for example about 1/10 of the period of the highest frequency or less.

The first component 420 has a first intensity 422 while the second component 430 has an intensity of zero or about zero (e.g., the second component 430 represents an off state of a laser providing the pulse signal 400). The first component 420, in contrast to the example discussed in connection with FIG. 2, may be understood as providing both a drive or excitation portion or component, as well as a read or data collection portion or component. As seen in FIG. 4, the first component 420 of the pulsed signal 400 includes a leading edge 424 and a trailing portion 426. The leading edge 424 may act to excite the sensor, while the trailing portion 426 may correspond to a settling of the sensor (albeit while still being excited by the first component 420) over which reflections of the pulsed signal 400 may be read by the interrogation unit 110 and used to determine one or more resonant frequencies. (It may be noted that the portion of the signal leading to the leading edge 424 is depicted as vertical in the illustrated embodiment, but in practice may have a slope slightly less than vertical corresponding to the turn-on time or rise time, for example due to time constants of electronics used to produce the signal.) For the example pulsed signal 400 depicted in FIG. 4, the same component (e.g., high energy portion or first component 420) of the pulsed signal is used for driving and reading the sensor. For example, the interrogation unit 110 may disregard reflections of the first component 420 corresponding to the leading edge 424 and use only reflections of the trailing portion 426 to provide frequency information to be used in determining one or more resonant frequencies. The first intensity 422 in various embodiments may be configured to provide sufficient energy to cause the sensor to vibrate at sufficiently high amplitudes to provide enough information to determine one or more resonant frequencies, while still allowing some amount of ring down during the trailing portion 426 for reading reflections of the pulsed signal 400.

The first component 420 has a duration 421 and the second component 430 has a duration 431. In the illustrated embodiment, the duration 421 and the duration 431 are equal, with each component thus having a duration of half of the period 410. Because the first portion 420 of the pulsed signal 400 is used for both excitation and reading, the duration 421 of the first component 420 may be relatively long compared to the duration 221 of the first component 220 of the pulsed signal 200. Because the duration of a high energy portion of the signal 400 is relatively longer, the embodiment depicted in FIG. 4 may provide increased energy delivered to the sensor compared to the embodiment depicted in FIG. 2. The embodiment of FIG. 4 thus provides for a relatively simple on-off cycling of a single laser to drive and read a given sensor, but may deliver increased energy to the sensor over that from the pulsed signal 200. As also discussed in connection with FIG. 2, in some embodiments a plurality of sensors may be employed in conjunction with pulsed signals similar to the pulsed signal 400, with each sensor having a laser dedicated thereto, and with each of the lasers occupying a different wavelength or bandwidth, so that the signal for any given laser may be combined with signal from other lasers on a single cable and split off, based on wavelength, to an appropriate corresponding sensor. Thus, in some embodiments (e.g., as shown in FIG. 2) a high intensity portion of a pulse is used to excite a sensor and a low intensity portion is used to read reflections, while in other embodiments (e.g., as shown in FIG. 4, a high intensity portion of a pulse is used to both excite a sensor and read reflections. Further, in various embodiments, the same laser may be used for both excitation and reading, while, in other embodiments, different lasers are used to excite and to read the sensor.

Returning to FIG. 1, the reading module 114 is configured to receive the return signal 170 (either directly or indirectly in raw or processed condition) including reflections of the pulsed signal 160 off the sensor 140. The depicted reading module 114 is further configured to read the reflections of at least part of a component. In various embodiments, the reading module 114 may read the reflections of all or a portion of the low energy portion of the pulsed signal 160 (e.g., second component 230 of the pulsed signal 200), while in other embodiments the reading module 114 may read the reflections of a portion of the high energy portion of the pulsed signal 160 (e.g., trailing portion 426 of the first portion 420 of the pulsed signal 400). As used herein, to read a signal or portion thereof may be understood as including collecting information over at least one sampling period of the signal or portion thereof. For example, the reading module 114 may store the portions of the reflected signal corresponding to a reading portion of the pulsed signal over a number of samples, and average the results to provide an averaged signal profile, which may be used to provide resonant frequency information, while disregarding or not reading other portions, such as portions corresponding to an excitation or drive portion of the pulsed signal. It may be noted that the signal sampling rate may have a frequency of about twice the highest frequency to be measured. In some embodiments, sensors may be employed having vibrations up to about 100 kiloHertz, and the signal may be measured at a rate of about 200 kiloHertz or higher. In some embodiments, however, techniques may be employed to sample at lower frequencies (e.g., if an approximate frequency of one or more vibrational modes is already known).

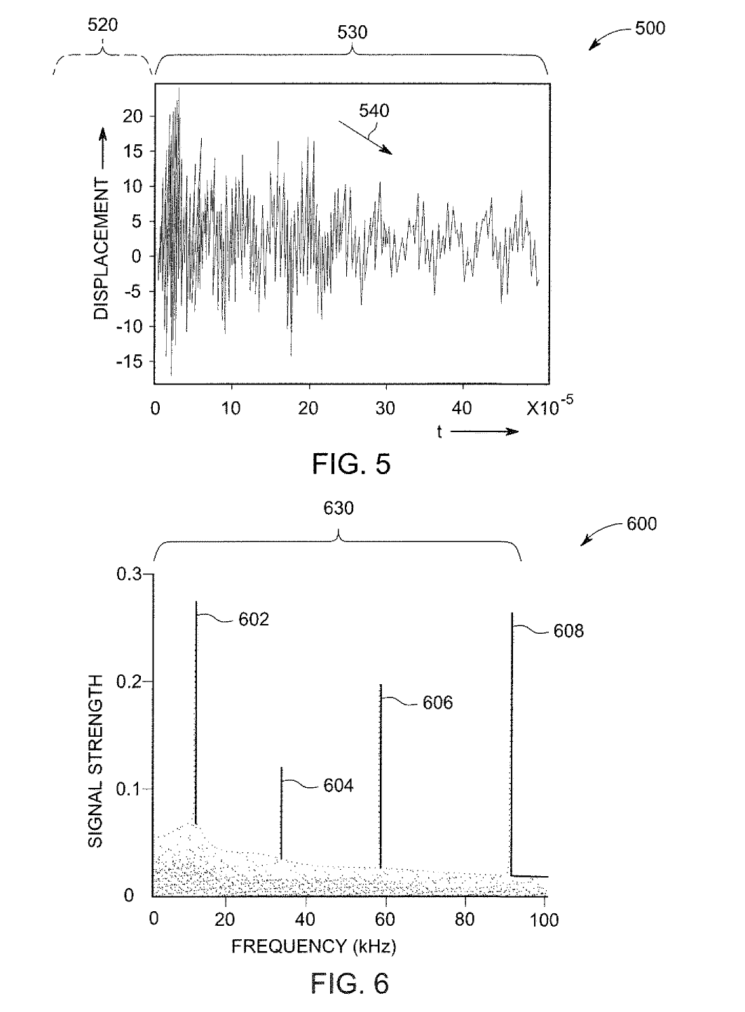

FIG. 5 illustrates an example of a reflection signal 500 in accordance with various embodiments. The depicted reflection signal 500 is shown for a portion of a period and is plotted on a vertical axis corresponding to displacement (e.g., amplitude of a reflected signal) and a horizontal axis corresponding to time. The depicted reflection signal 500 has a first component 520 (not shown, indicated by phantom-lined brackets in FIG. 5) corresponding to an excitation portion of a pulsed signal of which the reflection signal 500 is a reflection, and a second component 530 corresponding to a reading portion of the pulsed signal. As seen in FIG. 5, the reflection signal oscillates generally about a zero value and has generally decreasing slope 540 of maximum amplitude. The second component 530 in the illustrated embodiment corresponds to a ring down period following a high energy pulse or between high energy pulses. For example, the second component may represent, depict, or describe reflections of the second component 230 of the pulsed signal 200. The reflection signal 500 may be for a single period or cycle, or may represent an averaging of a number of cycles. A number of cycles may be sampled and averaged, for example, to address noise concerns that may arise for a single sample or a low number of samples.

Based on model calculations (e.g., using finite element modeling techniques) of various embodiments of sensors, it may be noted that, in some embodiments, high frequency modes, which are present immediately after initiation of a high energy pulse, tend to damp more quickly than lower frequency modes. Generally, depending on the resonator (e.g., the resonator of a MEMS sensor) design, some modes will involve more energy dissipation from the motion of the resonator and will damp more quickly than other modes. In some embodiments, the amplitude of higher damped modes may be enhanced via more quickly pulsing the laser. For example, to obtain an optimal or improved signal-to-noise ratio (SNR), the laser may be pulsed just quickly enough so that the amplitude of one or more eigenmodes of interest from a first high energy pulse has just faded into background noise as the following high energy pulse is delivered. It may be noted that any other eigenmodes still vibrating at the initiation of the following high energy pulse may either be in phase with the vibration of a given mode, in which case the amplitude of that mode will increase, or out-of-phase, in which case the amplitude of the mode will decrease. The rate of pulsing the laser may be chosen to obtain a desired SNR for one or more modes of interest. The rate therefore may be faster than the damping period of one of the modes, for example the mode having the highest Q.

The reading module 114 may receive a raw signal or information describing a number of cycles of a reading portion or component of a reflected signal, and average or otherwise combine the information into a representation corresponding to a single cycle. Further, the reading module 114 may derive, determine, or otherwise obtain a spectral resonance measurement of the averaged signal to provide frequency information (e.g., for analysis by the determination module 116). For example, the reading module 114 may include processing circuitry configured to perform a Fourier transform on an averaged signal representing the reflections received over a number of samples of a reading portion or component of a reflection signal.

FIG. 6 depicts an example spectral resonance 600 of the reflective signal 500 in accordance with various embodiments. For example, the reflective signal 500 (which may represent an average of a number of samples of a reading portion or component of a reflected signal) may be Fourier transformed to provide the spectral resonance 600. The spectral resonance 600 depicted in FIG. 6 is plotted on a vertical axis of signal strength and a horizontal axis of frequency. The various peaks or local maxima of the spectral resonance may be identified as resonant frequencies or resonant modes for the sensor over the time period of interrogation. For example, in the illustrated example, the spectral resonance 600 includes a first resonant mode 602 of about 12 kiloHertz (kHz), a second resonant mode 604 of about 33 kHz, a third resonant mode 606 of about 59 kHz, and a fourth resonant mode 608 of about 91 kHz. As discussed in more detail in the 296 application, the various resonant modes may be used to determine the temperature and pressure surrounding a given sensor.

To identify resonant modes of additional sensors, the reflection signals provided along a laser wavelength corresponding to each additional sensor may be averaged and converted to a spectral resonance for each additional sensor. The reading module 114 may be configured to provide sensor frequency information for each sensor based on a corresponding wavelength channel associated with each sensor, and the determination module 116 may determine at least one resonant frequency for each sensor based on the sensor frequency information corresponding to the given sensor.

The determination module 116 depicted in FIG. 1 is configured to receive the frequency information (e.g., resonant frequency information or information from which resonant frequency may be determined or derived) from the reading module and to deter mine at least one resonant frequency of at least one sensor based on the frequency information. For example, the determination module 114 may identify one or more resonant frequencies by identifying peaks or local maxima of a spectral frequency representation (e.g., spectral frequency 600). In some embodiments, one resonant frequency for at least one sensor may be determined. In other embodiments, more than one resonant frequency for at least one sensor may be determined and used for simultaneous determination of pressure or temperature, for example, as discussed in more detail in the 296 application. The determination module 116 may be configured to identify resonant frequencies for a given sensor and, based on the resonant frequencies, determine a pressure and/or a temperature for the given sensor.

The laser module 130 in the illustrated embodiment is configured to provide laser or light energy (e.g., the pulsed signal 160) to the sensor 140 via the cable 150. The depicted laser module 130 is also configured to receive the reflections 170. For example, the laser module 130 may include one or more detectors (e.g., one detector per sensor) that receive the reflections corresponding to the wavelength associated with a given laser/sensor/detector combination. The laser module 130 (e.g., the detector(s)) may then provide the reflections (either raw or processed) to the interrogation unit 110. In other embodiments, the detector(s) may be understood as part of the interrogation unit 110 (e.g., as a part of the reading module 114). As indicated herein, the laser module 130 may include one or more lasers. For example, a single laser may be used to drive or excite and read a single sensor. As another example, a plurality of sensors may each have a laser dedicated thereto based on wavelength, so that each laser may send a portion of a signal along a shared cable, with the appropriate portion split off for each sensor. Further, in some embodiments, a single laser emitting n wavelengths (e.g., emits laser energy over distinct wavelengths, for example over n evenly spaced wavelength bands or channels) may be used to drive n sensors. In some embodiments, a single wavelength with a high energy pulse may be used for n sensors. As one example of the use of a single wavelength, as the pulse travels down the cable, splitters may be used to tap off some of the pulse power to individual sensors. The reflected pulse may then be read by a separate read laser or by the low energy portion of the drive pulse. Thus, in some embodiments, it may be possible to use 2, or even 1 laser for interrogating n sensors.

In various embodiments, the laser module 150 may include at least one drive or excitation laser and at least one read laser. The excitation laser and read laser may be operated at the same wavelength or at different wavelengths. For example, in various embodiments, the laser module may include n (where n is an integer) lasers for n sensors, or may include n+1 lasers for n sensors, thereby reducing the number of lasers (and cables) required in comparison to techniques that require 2 lasers for each sensor. In other embodiments, 2 lasers may be used per sensor while still realizing other benefits of the presently disclosed inventive subject matter, such as the use of a common shared cable and resulting reduction in number of cables, and the elimination of a feedback circuit for laser operation to modulate a laser at a resonant frequency. In some embodiments, the laser module 130 may include a tunable laser that may be used to read information from multiple sensors serially.

The sensor 140 receives the pulsed signal 160 and provides the reflections 170 responsive to the pulsed signal 160. The reflections 170 may be used to identify resonant frequencies or modes of the sensor 140, which may in turn be used to determine an environmental parameter of the remote environment 101, such as a pressure and/or temperature of a location within the remote environment 101 proximate the sensor 140.

The sensor, for example, may be configured as a MEMS sensor. (For additional details regarding MEMS sensors, see the 296 application.) Generally, in various embodiments, a sensor may be configured to have two or more distinct resonant frequencies, or modes. Depending on the temperature and pressure of the environment in which the sensor is disposed, the first and second resonant frequencies may vary. Additionally, the type, direction, and/or amount of variance of the resonant frequencies with respect to changes in temperature and pressure may differ from each other. As one example, a first resonant frequency may increase with an increase in temperature while a second resonant frequency may decrease with an increase in temperature. As another example, each of a first and second resonant frequencies may increase (or decrease) with an increase in temperature, but the first resonant frequency may increase (or decrease) at a higher rate with temperature change than the second resonant frequency. As one more example, the type or shape of variance with temperature change may differ. For example, a first resonant frequency may vary linearly with temperature change, while a second resonant frequency may vary non-linearly with temperature change. Because the variabilities (or changes in resonant frequency) differ for the first and second resonant frequencies, different combinations of first and second resonant frequencies may correspond to and define particular combinations of pressure and temperature. It may be noted that in other embodiments, only one resonant frequency may be determined, and used, for example, to determine a pressure.

The cable 150 is configured to provide a conduit for passage of the pulsed signal 160 (or portions thereof) to one or more sensors (e.g., the sensor 140), and for passage of the reflections 170 from one or more sensors to the laser module 130 and/or the interrogation unit 110. The cable 150, for example, may be a fiber optic cable. The fiber optic may be provided within a casing, and may be disposed in a protective shield or casing, such as ¼″ stainless steel tube, to protect the cable 150 from harsh conditions within the remote environment 101. An internal sleeve and/or a gel, liquid, or other material may be interposed between the cable 150 and the stainless steel tube.

It may be noted that more than one sensor 140 may be operably coupled to the laser module and/or the interrogation unit 110 via the cable 150, thereby eliminating the need for a multiplicity of cables running through the remote environment 101 when using multiple sensors (e.g., sensor disposed at different locations within the remote environment 101). For example, the cable 150 may include or otherwise be associated with WDMs disposed along a length of the cable 150, with each WDM associated with a sensor. The WDMs along the length of the cable 150 may each be configured to split off a particular wavelength assigned to or associated with a particular sensor (and return reflections at the particular wavelength to the cable 150 for return to the laser module and/or interrogation unit 110). A given laser and sensor may form a pair having an assigned wavelength, with signals sent and received along that wavelength associated with the sensor and used to determine one or more resonant frequencies of the sensor.

For example, as seen in the view provided in the lower right hand portion of FIG. 1, the cable 150 may be operably connected to a first sensor module 141, a second sensor module 142, and a third sensor module 143. More or fewer sensor modules may be used in various embodiments. Each sensor module may include a MEMS sensor and a WDM configured to provide the MEMS sensor with a particular wavelength of the pulsed signal 160. The sensor modules may be spliced into the cable 150 as shown in FIG. 1, with the sensor modules space a desired distance apart to obtain distributed measurements of the remote environment 101. The interrogation unit 110 may associate reflections received (and resonant frequencies for the reflections) with the corresponding sensor based on the wavelength assigned to the sensor, and thus separate the reflections and resonant frequency by sensor to determine pressure and/or temperature for each sensor. The sensor modules may be coupled to the cable 150 as a pre-formed unit, with cable/sensor module assembly then positioned as desired in the remote environment 101 for measurement of the remote environment.

FIG. 7 provides a schematic view of an example measurement system 700 that includes individual laser configured to provide read and excitation portions of a pulsed signal (e.g., the first component 220 and the second component 230 of the pulsed signal 200), with each laser dedicated to a particular sensor positioned in a remote location 704. The measurement system 700 includes a first laser module 710, a second laser module 720, a third laser module 730, a junction module 740, a cable 750, a first divider 742 operably coupled to a first sensor 718 via a first path 717, and a second divider 744 operably coupled to a second sensor 728 via a second path 727 and to a third sensor 738 via a third path 737. Each of the laser modules may be configured to provide a pulsed signal (e.g., pulsed signal 200 or pulsed signal 400, among others) to the cable 750 via the junction module 740. Each laser module produces a pulsed signal along a particular wavelength exclusively assigned to that laser. Thus, each of the laser modules provides a signal having a unique, identifiable wavelength. The combined pulsed signals are then distributed to the sensors 718, 728, 738 via the dividers 742, 744, with the dividers configured so that each sensor receives the portion of the combined signal provided by a laser assigned to that sensor. Reflections from the sensor are returned to the laser modules, with the junction module 740 separating the reflections and directing the reflections from each sensor to the laser module that provided the portion of the combined signal that was provided that particular sensor. For ease of illustration, in FIG. 7, lasers are labelled “L,” detectors are labelled “D,” circulators are labelled “C,” dividers are labelled “Div.,” and sensors are labelled “S.”

As seen in FIG. 7, the first laser module 710 includes a laser 711, a detector 712, and a circulator 713. The laser 711 is configured to provide a pulsed signal along a wavelength uniquely assigned to the first laser module 710, and the detector 712 is configured to detect a signal reflected off of an associated sensor. The laser 711 and detector 712 may be operably coupled to or form a portion of an interrogation unit (not shown in FIG. 7) such as, for example, the interrogation unit 110 discussed in connection with FIG. 1. The interrogation unit 110 may be configured to control the laser 711 to deliver the pulsed signal and to use the reflections detected by the detector 712 to determine resonant frequency(ies) of the associated sensor (e.g., the first sensor 718). The circulator 713 is configured to direct the pulsed signal sent from the laser via path 714 to the junction module 740 via path 715, and to direct reflections from the first sensor 718 received via the junction module 740 via path 715 to the detector via path 716. The various paths discussed herein may be configured as fiber optic cables, for example.

The second laser module 710 includes a laser 721, a detector 722, and a circulator 723. The laser 721 is configured to provide a pulsed signal along a wavelength uniquely assigned to the second laser module 720, and the detector 722 is configured to detect a signal reflected off of an associated sensor. The laser 721 and detector 722 may be operably coupled to an interrogation unit configured to control the laser 721 to deliver the pulsed signal and to use the reflections detected by the detector 722 to determine resonant frequency(ies) of the associated sensor (e.g., the second sensor 728). The circulator 723 is configured to direct the pulsed signal sent from the laser via path 724 to the junction module 740 via path 725, and to direct reflections from the second sensor 728 received via the junction module 740 via path 725 to the detector via path 726.

Similarly, the third laser module 730 includes a laser 731, a detector 732, and a circulator 733. The laser 731 is configured to provide a pulsed signal along a wavelength uniquely assigned to the third laser module 730, and the detector 732 is configured to detect a signal reflected off of an associated sensor (e.g., the third sensor 738). The laser 731 and detector 712 may be operably coupled to an interrogation unit configured to control the laser 731 to deliver the pulsed signal and to use the reflections detected by the detector 732 to determine resonant frequency(ies) of the associated sensor (e.g., the third sensor 738). The circulator 733 is configured to direct the pulsed signal sent from the laser via path 734 to the junction module 740 via path 735, and to direct reflections from the third sensor 738 received via the junction module 740 via path 735 to the detector 732 via path 736.

The junction module 740 is configured to receive the individual pulsed signals from the laser modules and combine the pulsed signals into a single combined signal sent to the dividers via path 750. The junction module 740 is also configured to receive a combined reflection signal including the reflections from each sensor and separate the combined signal into components, by wavelength, for transmission to the laser modules. The junction module 740 may be, for example, an arrayed waveguide grating (AWG).

The dividers, which may be configured as WDMs, are configured to separate off particular wavelengths from the combined pulsed signal transmitted from the junction module 740 and direct particular wavelengths to appropriate sensors. The dividers are also configured to receive reflections from an associated sensor and combine the reflections from the associated sensor with reflections of other sensors (e.g., sensors positioned downstream of the particular divider) to form the combined reflection signal provided to the junction module 740. If, for example, the laser 711 of the first laser module 710 is at 1310 nanometers (e.g. within a relatively narrow bandwidth generally centered around 1310 nanometers), the first divider 742 is configured to split off light at 1310 nanometers to the first sensor 718 via path 717 and remaining light to the second divider 744 via path 752. The second divider 744 splits off light at the wavelength of the laser 721 of the second laser module 720 to the second sensor 728 via path 727, and remaining light to the third sensor 738 via path 737. Because the third sensor 728 is the last remaining sensor of the illustrated embodiment, the third sensor does not require a dedicated divider, but instead can receive all remaining light, which will include light along the wavelength assigned to the laser 731 of the third laser module 730. The reflected light from the sensors is returned to the junction module 740 via the paths and dividers discussed above, generally in reverse order compared to the provision of laser energy to the sensors.

When the reflections are received at the junction module 740, the junction module 740 receives the combined reflection signal and separates the reflection signal into components sent to particular laser modules based on the wavelengths of the particular laser modules. Reflected light along the wavelength of the laser 711 is transmitted to the first laser module 710, reflected light along the wavelength of the laser 721 is transmitted to the second laser module 720, and reflected light along the wavelength of the laser 731 is transmitted to the third laser module 730.

Each laser is associated with a corresponding detector and sensor based on wavelength. By associating each signal with the detector from which the signal was obtained, each signal (and any related parameters such as temperature and pressure determined using each signal) may be associated with the sensor corresponding or assigned to the identified detector. With each sensor associated with a unique wavelength of reflections, the sensors may be distributed about a shared cable while still allowing for ready identification of portions of signals corresponding to each sensor, eliminating the need for separate cables for each sensor. It may be noted that while only three sensors are shown, the general principles discussed herein may be applied to embodiments having different numbers of sensors, and that different numbers of sensors operably coupled to a single cable may be employed in various embodiments. Further, it may be noted that each laser module of a given system may produce a pulsed signal that is similar in general type, shape, and amplitude to one or more pulsed signals produced by other laser modules, or that a given laser module may produce a pulsed signal that is substantially different from one or more pulsed signals produced by other laser modules. A pulsed signal may be tailored for a type of sensor or individual sensor, with different types of sensors coupled to a shared cable in various embodiments.

FIG. 8 provides a schematic view of an example measurement system 800 that includes an excitation laser configured to provide an excitation portion of a pulsed signal (e.g., the first component 220 of the pulsed signal 200), and a read laser configured to provide a read portion of a pulsed signal (e.g., the second component 230 of the pulsed signal 200). The depicted example measurement system 800 includes an excitation laser 810 (or drive laser), a pulse selection module 812, an absorption module 814, a read laser 820, a circulator 822, a WDM 824, a detector 826, WDM 830, a splitter module 840, and a sensor 850. Additional detectors may be employed in various embodiments.

The excitation laser 810 is configured to provide an excitation or drive portion of a pulsed signal, and the read laser 820 is configured to provide a read portion of the pulsed signal, with the reflections of the read portion used to identify one or more resonant frequencies of the sensor 850. The read portion of the signal may be configured to correspond with a ring down period of the sensor 850 following excitation by a high energy pulse of the excitation laser. The wavelengths of the read laser 820 and the excitation laser 810 may be the same in some embodiments or different in other embodiments.

In the depicted example, the excitation laser 810 has an average output power of about 250 milliWatts, a wavelength of about 1550 nanometers, and pulse repetition rate of about 10 kHz. Because 10 kHz may be too rapid of a rate to allow for effective reading of reflections during a ring down period between delivery of the high energy pulses, the pulse selection module 812 may be employed to selectively pick pulses allowed to travel to the sensor 850 (and/or any other sensors), and to discard other pulses. For example, the pulse selection module 812 may be an acoustic optical (AO) modulator configured to allow certain pulses to travel to the sensor 850 (via the WDM 830) and other pulses to the absorption module 814, which may be understood as a beam dump. The excitation laser provides a pulse of relatively high energy at a desired pulse interval to the sensor 850 via the WDM 830.

The depicted read laser 820, for example, may be a diode laser having a wavelength of about 1310 nanometers, which may be provided at a constant relatively low power level. The energy produced by the read laser 820 is directed to the WDM 830 via the circulator 822, and combined with the pulse from the excitation laser 810 by the WDM 830.

The combined signal produced by the excitation laser 810 and the read laser 820 travels along a fiber optic cable from the WDM 830 to the splitter module 840, which splits a portion of the combined signal to the sensor 850, and the remainder to one or more additional sensors (not shown). It may be noted that the WDM may receive additional read signals from additional read lasers (not shown) for the additional sensors. The high energy pulse from the excitation laser 810 may be relatively short compared to the periods of the resonant modes of the sensor 850. In some embodiments, absorption of the high energy pulse of the pulsed signal causes a resonator of the sensor 850 to heat and expand, which in turn causes the resonator to begin vibrating at the various eigenmodes of the resonator. The resonator may form one mirror of an optical cavity, with additional reflection coming from non-vibrating surfaces in the optical path, for example inner and outer surface of a cap of a die of the sensor 850. The low power signal from the read laser 820 is reflected from the optical cavity, and the amplitude is modulated by the vibrating resonator inside the cavity. The reflected light may be detected (e.g., by the detector 826) during a time between high energy pulses and used to determine the resonant frequencies of the sensor 850.

The high energy pulse of the combined pulse signal causes an excitation and subsequent ring down of the sensor 850 (e.g., a resonator of the sensor 850), which may be read during a read portion of the pulsed signal using the signal from the read laser 810. Reflections from the sensor 850 are transmitted to the splitter module 840, where the reflections from the sensor 850 are combined with reflections from other sensors (not shown). The reflections from the sensor 850 then travel from the splitter module 840 to the WDM 830 which separates reflections along the 1310 nanometer wavelength to the circulator 822, from where the separated reflections travel to the detector 826 via the WDM 824. It may be noted that in various alternate embodiments, the WDM 830 may be replaced, for example, with a splitter module (e.g., a 50/50 splitter) or, as another example, with a polarization combiner.

In various embodiments, the read laser 820 may be configured as a diode laser having a wavelength of about 1550 nanometers (e.g., the same wavelength as the excitation laser 810). However, combining the two lasers at the same wavelength may require either a coupler (for which some light is lost for both sources), or a narrow WDM that may minimize or reduce the light lost from either source, but provides increased expense and may not function as well at higher temperatures.

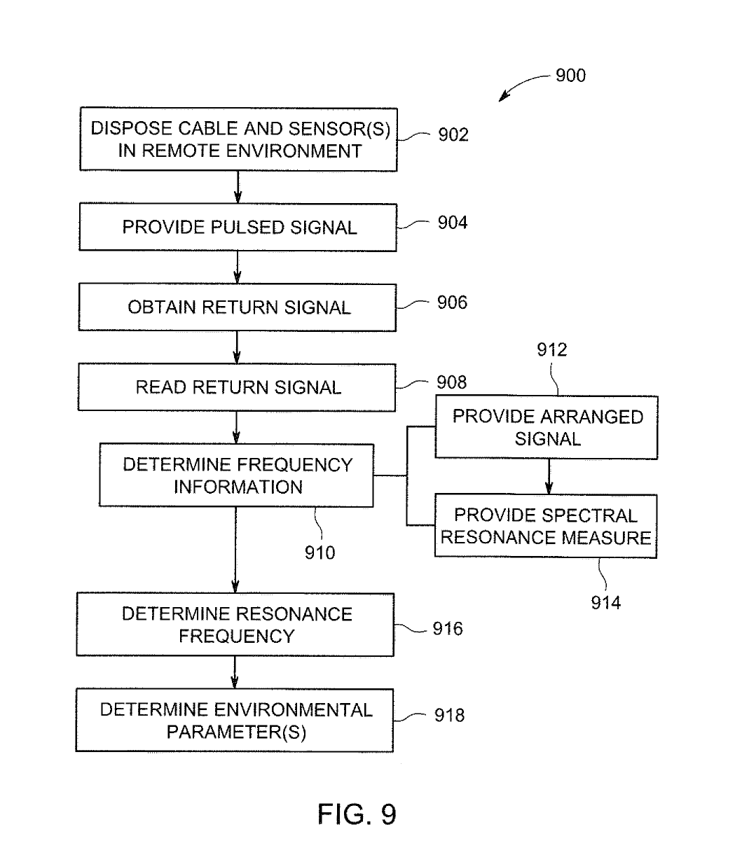

FIG. 9 provides a flowchart of a method 900 for determining pressure and/or temperature, for example temperature and/or pressure of one or more locations of a remote environment in which one or more sensors are disposed. In various embodiments, the method 900, for example, may employ structures or aspects of various embodiments (e.g., systems and/or methods) discussed herein. In various embodiments, certain steps may be omitted or added, certain steps may be combined, certain steps may be performed simultaneously, certain steps may be performed concurrently, certain steps may be split into multiple steps, certain steps may be performed in a different order, or certain steps or series of steps may be re-performed in an iterative fashion. In various embodiments, portions, aspects, and/or variations of the method 900 may be able to be used as one or more algorithms to direct hardware to perform operations described herein.

At 902, a cable having one or more sensors operably coupled thereto is disposed with a remote environment. The sensors, for example, may be MEMS sensors configured for detection of temperature and/or pressure based on the resonant frequencies of the sensors. The sensors may be disposed at predetermined lengths along the cable length. Each sensor may have a WDM or similar device coupled thereto and configured to provide a unique wavelength of energy from the cable to the sensor. The cable may be operably coupled to a laser module configured to provide a pulsed signal to the cable.

At 904, a pulsed signal is provided. Generally, the pulsed signal has a high energy portion (e.g., first component 220 of the pulsed signal 200) and a low energy portion (e.g., second component 230 of the pulsed signal 200). The high energy portion may be configured to excite a sensor to vibrate at one or more resonant frequencies. The low energy portion allows a period of ring down of the sensor between high energy pulses. For embodiments using only a single sensor, a single pulsed signal may be provided. For embodiments using a plurality of sensors, a pulsed signal for a wavelength assigned to each sensor may be generated by corresponding lasers and combined to form a combined signal provided to the cable for subsequent separation and distribution of individual signals (separated based on wavelength) to individual sensors. Each sensor may be associated with the wavelength produced by a particular laser. In some embodiments, a single laser may provide the pulsed signal, while in other embodiments, two lasers may be used to provide a pulsed signal (e.g., a first laser provides a high energy excitation pulse, and a second laser provides a low energy read signal).

At 906, a return signal is obtained. For example, reflections from a sensor may be redirected along the cable to a detector configured to detect the reflections. In embodiments using plural sensors, each detector may be provided with a portion of the reflection signal corresponding to a particular wavelength (e.g., the wavelength of a corresponding laser) so that each detector detects the portion of the reflection signal provided by a particular sensor. The return signal may be obtained (e.g., received) by one or more processing units (e.g., interrogation unit 110).

At 908, the return signal is read, for example by one or more processing unit (e.g., interrogation unit 110). The return signal from one or more sensors may be collected by the processing unit, and, for example, organized or maintained separately by wavelength (e.g., by detector from which signal or information is received). The return signal may be collected and stored for a number of samples (e.g., 100 samples or 1000 samples, among others). Further, the return signal may only be read over a portion of the period of the reflections, such as all of or a part of a ring down period of the sensor between high energy pulses. For example, in some embodiments, the return signal may only be read for reflections of a low energy component of the pulsed signal. In some embodiments, the return signal may only be read for reflections of a trailing portion of a high energy portion of the pulsed signal. It may be noted that, in embodiments using a dedicated read laser for each sensor, the information for each sensor may be read simultaneously or concurrently. For embodiments using a single laser (e.g., a tunable laser) to read information from all sensors, the information for each sensor may be read serially or sequentially (e.g., one at a time) as the tunable laser scans across the pertinent wavelengths.

At 910, frequency information (e.g., resonant frequency information) is determined based on the reading of the return signal (e.g., reflections of the pulsed signal) from 908. For example, at 912, the information from the read portions of the samples read at 908 may be combined and averaged, for example to reduce the effects of noise. At 914, the averaged signal is converted to a spectral resonance measure, for example by a Fourier transform of the averaged signal. The frequency information may be determined by the one or more processing unit (e.g., interrogation unit 110). In embodiments using multiple sensors, the portions of the return signal for each sensor may be segregated (e.g., by wavelength of signal and/or by detector that is source of portion of signal), with each separate portion of the return signal separately combined or averaged and converted to a spectral resonance measure. The frequency information (e.g., resonant frequency information) may be used to determine one or more resonant frequencies.

At 916, a resonance frequency is determined, for example by the one or more processing unit (e.g., interrogation unit 110). The resonance frequency is determined based on the frequency information determined or provided at 910. For example, one or more resonant frequencies for each sensor may be determined based on peaks or local maxima in the spectral resonance measure provided at 914. The resonant frequencies for each sensor may be separately determined for embodiments having multiple sensors.

At 918, one or more environmental parameters are determined, for example, by the one or more processing unit (e.g., interrogation unit 110). For example, a particular pressure may be associated with a particular resonance frequency. As another example, a particular pressure and temperature combination may be associated with a particular combination of two or more resonant frequencies for any given sensor. By determining the resonant frequencies for a given sensor, and using a predetermined relationship correlating the resonant frequencies with a temperature and pressure combination for the given sensor (e.g., a relationship determined or provided via a calibration of the sensor) the pressure and temperature of the surroundings of a given sensor may be determined.

For example, in various embodiments, a pulsed signal may be used to interrogate one more sensors (e.g., one or more MEMS sensors), for example to determine pressure and/or temperature in a remote location. In various embodiments, the number of lasers required to interrogate one or more sensors is reduced. Various embodiments additionally or alternatively provide for the convenient use of a single cable to provide drive and read signals to plural sensors and to receive reflections from the sensors. Various embodiments also eliminate the need for a feedback loop used to modulate a drive signal for interrogating a sensor.

It should be noted that the particular arrangement of components (e.g., the number, types, placement, or the like) of the illustrated embodiments may be modified in various alternate embodiments. In various embodiments, different numbers of a given module or unit may be employed, a different type or types of a given module or unit may be employed, a number of modules or units (or aspects thereof) may be combined, a given module or unit may be divided into plural modules (or sub-modules) or units (or sub-units), a given module or unit may be added, or a given module or unit may be omitted.

It should be noted that the various embodiments may be implemented in hardware, software or a combination thereof. The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid state drive, optical drive, and the like. The storage device may also be other similar means for loading computer programs or other instructions into the computer or processor.

As used herein, the term “computer,” “controller,” and “module” may each include any processor-based or microprocessor-based system including systems using microcontrollers, reduced instruction set computers (RISC), application specific integrated circuits (ASICs), logic circuits, GPUs, FPGAs, and any other circuit or processor capable of executing the functions described herein. The above examples are exemplary only, and are thus not intended to limit in any way the definition and/or meaning of the term “module” or “computer.”

The computer, module, or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer, module, or processor as a processing machine to perform specific operations such as the methods and processes of the various embodiments described and/or illustrated herein. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the faint of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program. The individual components of the various embodiments may be virtualized and hosted by a cloud type computational environment, for example to allow for dynamic allocation of computational power, without requiring the user concerning the location, configuration, and/or specific hardware of the computer system.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

This written description uses examples to disclose the various embodiments, and also to enable a person having ordinary skill in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or the examples include equivalent structural elements with insubstantial differences from the literal languages of the claims.

What is claimed is:

1. A sensor interrogation unit comprising:
a control module configured to control one or more lasers to provide a pulsed signal to at least one sensor, each period of the pulsed signal having a first component having a first intensity and a second component having a second intensity that is lower than the first intensity;
a reading module configured to receive at least one return signal comprising reflections of the pulsed signal from the at least one sensor, to read reflections of one of the first component or the second component, and to provide resonant frequency information based on the read reflections; and
a determination module configured to determine at least one resonant frequency of the at least one sensor based on the resonant frequency information.

2. The sensor interrogation unit of claim 1, wherein the reading module is configured to provide the resonant frequency information using reflections of the second component of the pulsed signal but not reflections of the first component of the pulsed signal.

3. The sensor interrogation unit of claim 1, wherein the second component has an intensity of about zero, wherein the reading module is configured to provide the resonant frequency information using reflections of the first component of the pulsed signal.

4. The sensor interrogation unit of claim 1, wherein the at least one sensor includes a micro-electromechanical system (MEMS) sensor, and wherein the determination module is further configured to determine at least one of a pressure or a temperature of an environment in which the MEMS sensor is disposed based on the determined at least one resonant frequency.

5. The sensor interrogation unit of claim 1, wherein the at least one sensor includes plural sensors operably coupled to the sensor interrogation unit via a shared cable, wherein each sensor is associated with a wavelength channel, wherein the reading module is configured to provide sensor frequency information for each sensor based on the corresponding wavelength channel, and wherein the determination module is configured to determine at least one resonant frequency for each sensor based on the corresponding sensor frequency information.

6. The sensor interrogation unit of claim 1, wherein the reading module is configured to obtain plural samples of the reflections, combine the samples to provide an averaged signal, and obtain a spectral resonance measurement of the averaged signal to provide the resonant frequency information.

7. The sensor interrogation unit of claim 1, wherein the control module is configured to control a single laser to transmit at least a portion of the first component of the pulsed signal and at least a portion of the second component of the pulsed signal.

8. The sensor interrogation unit of claim 1, wherein the control module is configured to control an excitation laser to transmit at least a portion of the first component of the pulsed signal and a read laser to transmit at least a portion of the second component of the pulsed signal.

9. A method for interrogating at least one sensor comprising:
providing a pulsed laser signal to at least one sensor, each period of the pulsed laser signal having a first component having a first intensity and a second component having a second intensity that is lower than the first intensity;
obtaining at least one return signal comprising reflections of the pulsed signal from the at least one sensor;
reading, with at least one processing unit, reflections of at least one of the first component or the second component;
determining, with the at least one processing unit, resonant frequency information of the return signal based on the reflections of the at least one of the first component or the second component that is read; and
determining, with the at least one processing unit, at least one resonant frequency of the at least one sensor based on the resonant frequency information.

10. The method of claim 9, wherein providing the pulsed laser signal includes providing the first component with an excitation laser and providing the second component with a read laser.

11. The method of claim 9, wherein providing the pulsed laser signal comprises providing at least a portion of the first component and at least a portion of the second component with a single laser.

12. The method of claim 9, wherein the second component has an intensity of about zero, wherein determining the resonant frequency information comprises determining frequency information for reflections of the first component of the pulsed signal.

13. The method of claim 9, wherein determining the resonant frequency information comprises determining frequency information for reflections of the second component of the pulsed signal but not frequency information for reflections of the first component of the pulsed signal.

14. The method of claim 9, wherein the at least one sensor includes plural sensors operably coupled to the at least one processing unit via a shared cable, wherein each sensor is associated with a wavelength channel, wherein determining the resonant frequency information includes determining sensor frequency information for each sensor based on the corresponding wavelength channel, and wherein determining the at least one resonant frequency comprises determining at least one resonant frequency for each sensor based on the corresponding sensor frequency information.

15. The method of claim 9, wherein determining the resonant frequency information comprises obtaining plural samples of the reflections, combining the samples to provide an averaged signal, and obtaining a spectral resonance measurement of the averaged signal to provide the frequency information.

16. A tangible and non-transitory computer readable medium for interrogating at least one sensor, the tangible and non-transitory computer readable medium comprising one or more computer software modules configured to direct one or more processors to:
provide a pulsed laser signal to at least one sensor, each period of the pulsed laser signal having a first component having a first intensity and a second component having a second intensity that is lower than the first intensity;
obtain at least one return signal comprising reflections of the pulsed signal from the at least one sensor;
read reflections of at least one of the first component or the second component;
determine resonant frequency information of the return signal based on the reflections of the at least one of the first component or the second component that is read; and
determine at least one resonant frequency of the at least one sensor based on the resonant frequency information.

17. The computer readable medium of claim 16, wherein the computer readable medium is further configured to direct the one or more processors to determine the resonant frequency information using reflections of the second component of the pulsed signal but not using reflections of the first component of the pulsed signal.

18. The computer readable medium of claim 17, wherein the at least one sensor includes plural sensors operably coupled to the at least one processing unit via a shared cable, wherein each sensor is associated with a wavelength channel, wherein the computer readable medium is further configured to direct the one or more processors to:
determine sensor frequency information for each sensor based on the corresponding wavelength channel; and
determine at least one resonant frequency for each sensor based on the corresponding sensor frequency information.

19. The computer readable medium of claim 17, wherein the computer readable medium is further configured to direct the one or more processors to:
obtain plural samples of the reflections;
combine the samples to provide an averaged signal; and
obtain a spectral resonance measurement of the averaged signal to determine the resonant frequency information.

20. The computer readable medium of claim 17, wherein the computer readable medium is further configured to direct the one or more processors to provide at least a portion of the first component and at least a portion of the second component with a single laser.
